(19) United States
(12) Patent Application Publication
(10) Pub. No.: US 2026/0293446 A1
(43) Pub. Date: Sep. 24, 2026

(54) DISPLAY DEVICE

(71) Applicant: Magnolia White Corporation, Tokyo (JP)

(72) Inventors: Hiraaki KOKAME, Tokyo (JP); Akinori KAMIYA, Tokyo (JP)

(73) Assignee: Magnolia White Corporation, Tokyo (JP)

(21) Appl. No.: 19/570,195

(22) Filed: Mar. 18, 2026

(30) Foreign Application Priority Data
Mar. 18, 2025 (JP) 2025-043138

(51) Int. Cl. H10K 59/122; H10K 59/80

(52) U.S. Cl. CPC H10K 59/122; H10K 59/873

(57) ABSTRACT

According to one embodiment, a display device includes a first display element including a first organic layer emitting light in response to application of a voltage, a partition surrounding the first display element and including a conductive lower portion and an upper portion having an end portion protruding relative to a side surface of the lower portion, a first sealing layer continuously covering the first display element and a part of the lower portion and having a first end portion spaced apart from the upper portion via a first gap in a height direction of the partition, and a first barrier layer including an oxide and covering at least a part of an upper surface of the first sealing layer.

### CROSS-REFERENCE TO RELATED APPLICATIONS

This application is based upon and claims the benefit of priority from Japanese Patent Application No. 2025-043138, filed Mar. 18, 2025, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display device, a technique for improving the yield is required.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic cross-sectional view of the display device along the III-III line of FIG. 2.

FIG. 4 is a schematic cross-sectional view showing part of the display device according to the first embodiment in an enlarged manner.

FIG. 5 is a flowchart showing an example of a manufacturing method of the display device according to the first embodiment.

FIG. 6A is a schematic cross-sectional view showing a manufacturing process of the display device according to the first embodiment.

FIG. 6B is a schematic cross-sectional view showing a process following the process shown in FIG. 6A.

FIG. 6C is a schematic cross-sectional view showing a process following the process shown in FIG. 6B.

FIG. 6D is a schematic cross-sectional view showing a process following the process shown in FIG. 6C.

FIG. 6E is a schematic cross-sectional view showing a process following the process shown in FIG. 6D.

FIG. 6F is a schematic cross-sectional view showing a process following the process shown in FIG. 6E.

FIG. 6G is a schematic cross-sectional view showing a process following the process shown in FIG. 6F.

FIG. 6H is a schematic cross-sectional view showing a process following the process shown in FIG. 6G.

FIG. 6I is a schematic cross-sectional view showing a process following the process shown in FIG. 6H.

FIG. 6J is a schematic cross-sectional view showing a process following the process shown in FIG. 6I.

FIG. 6K is a schematic cross-sectional view showing a process following the process shown in FIG. 6J.

FIG. 7 is a schematic cross-sectional view of the configuration according to a comparative example.

FIG. 8 is a schematic cross-sectional view showing the first modified example.

FIG. 9 is a schematic cross-sectional view showing the second modified example.

FIG. 10 is a schematic cross-sectional view of a display device according to the second embodiment.

FIG. 11 is a schematic cross-sectional view describing another example applicable to a manufacturing method of the display device according to the second embodiment.

FIG. 12 is a schematic cross-sectional view of a display device according to the third embodiment.

### DETAILED DESCRIPTION

In general, according to one embodiment, a display device includes a first display element including a first organic layer emitting light in response to application of a voltage, a partition surrounding the first display element and including a conductive lower portion and an upper portion having an end portion protruding relative to a side surface of the lower portion, a first sealing layer continuously covering the first display element and a part of the lower portion and having a first end portion spaced apart from the upper portion via a first gap in a height direction of the partition, and a first barrier layer including an oxide and covering at least a part of an upper surface of the first sealing layer.

According to another embodiment, a display device includes a first display element including a first organic layer emitting light in response to application of a voltage, a partition surrounding the first display element and including a conductive lower portion and an upper portion having an end portion protruding relative to a side surface of the lower portion, a first sealing layer continuously covering the first display element and a part of the lower portion and having a first end portion spaced apart from the upper portion via a first gap in a height direction of the partition, and a first barrier layer including an oxide, covering at least a part of a wall surface at an end of the first gap, and not being interposed between the lower portion and the first sealing layer.

According to still another embodiment, a display device includes a first display element including a first organic layer emitting light in response to application of a voltage, a partition surrounding the first display element and including a conductive lower portion and an upper portion having an end portion protruding relative to a side surface of the lower portion, a first sealing layer continuously covering the first display element and a part of the lower portion and having a first end portion spaced apart from the upper portion via a first gap in a height direction of the partition, and a first barrier layer including a fluoride and covering at least a part of a wall surface of an end of the first gap.

These configurations can improve yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc. of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

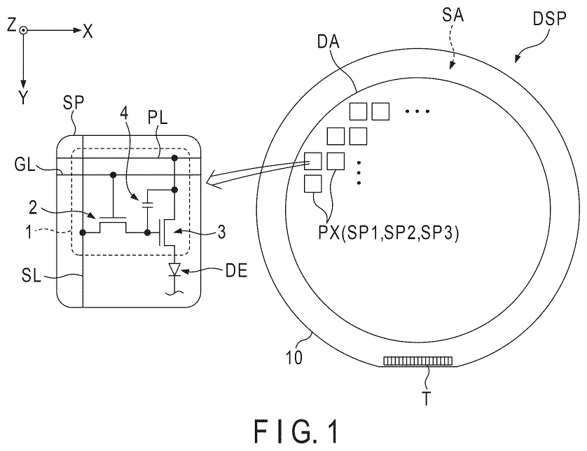

FIG. 1 is a view showing a configuration example of a display device DSP according to the first embodiment. The display device DSP comprises an insulating substrate 10. The substrate 10 has a display area DA for displaying images and a surrounding area SA around the display area DA. The substrate 10 may be glass or a resinous film having flexibility.

In the example of FIG. 1, the substrate 10 and the display area DA each have a circular shape in plan view. The shape of each of the substrate 10 and the display area DA in plan view is not limited to the circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP which display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T to which signals and voltages for driving the subpixels SP1, SP2, and SP3 are input. The terminal portion T is provided in the surrounding area SA. For example, a flexible printed circuit board, which applies the voltages and signals, is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL supplying a scanning signal to the pixel circuit 1 of each subpixel SP, a plurality of signal lines SL supplying a video signal to the pixel circuit 1 of each subpixel SP, and a plurality of power lines PL are provided in the display area DA.

A gate electrode of the pixel switch 2 is connected to the scanning line GL. One of a source electrode and a drain electrode of the pixel switch 2 is connected to the signal line SL. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the shown example. For example, the pixel circuit 1 may comprise more thin-film transistors and capacitors.

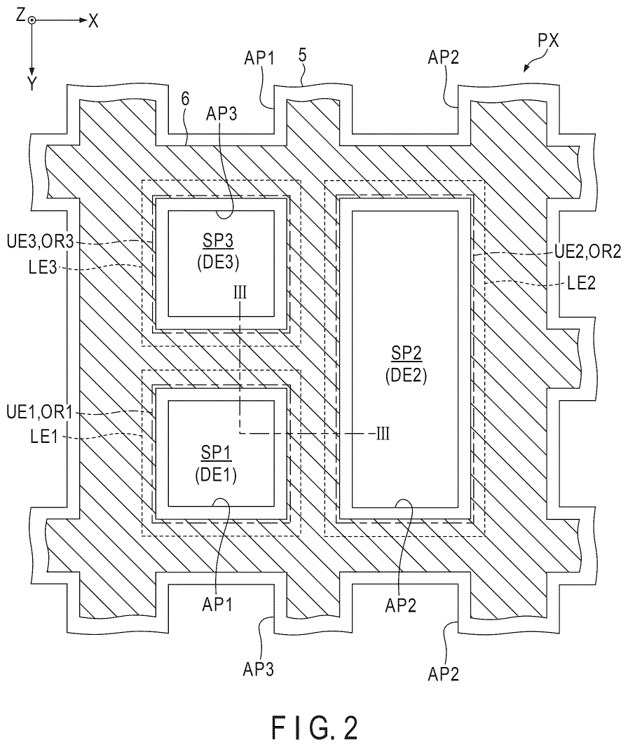

FIG. 2 is a schematic plan view showing an example of the layout of the subpixels SP1, SP2, and SP3 which constitute one pixel PX. In the example of FIG. 2, the subpixels SP1 and SP3 are arranged in the Y-direction. Further, the subpixels SP1 and SP3 are aligned with the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel apertures AP1 and AP3 are rectangles having the same planar size. In contrast, the pixel aperture AP2 is a rectangle extending longer in the Y-direction than the pixel apertures AP1 and AP3. The shape of the pixel apertures AP1, AP2, and AP3 is not limited to this example.

The subpixel SP1 comprises a lower electrode LE1, an upper electrode UE1, and an organic layer OR1 (the first organic layer), which overlap the pixel aperture AP1. The subpixel SP2 comprises a lower electrode LE2, an upper electrode UE2, and an organic layer OR2 (the second organic layer), which overlap the pixel aperture AP2. The subpixel SP3 comprises a lower electrode LE3, an upper electrode UE3, and an organic layer OR3 (the third organic layer), which overlap the pixel aperture AP3.

Parts overlapping the pixel aperture AP1 of the lower electrode LE1, the upper electrode UE1, and the organic layer OR1 constitute a display element DE1 (the first display element) of the subpixel SP1. Parts overlapping the pixel aperture AP2 of the lower electrode LE2, the upper electrode UE2, and the organic layer OR2 constitute a display element DE2 (the second display element) of the subpixel SP2. Parts overlapping the pixel aperture AP3 of the lower electrode LE3, the upper electrode UE3, and the organic layer OR3 constitute a display element DE3 (the third display element) of the subpixel SP3. Each of the display elements DE1, DE2, and DE3 may further include a cap layer to be described later. The rib layer 5 surrounds each of the display elements DE1, DE2, and DE3.

A conductive partition 6 is provided above the rib layer 5. The partition 6 functions as lines applying common voltage to the upper electrodes UE1, UE2, and UE3. The partition 6 entirely overlaps the rib layer 5 and has the same planar shape as the rib layer 5. That is, the partition 6 surrounds each of the display elements DE1, DE2, and DE3.

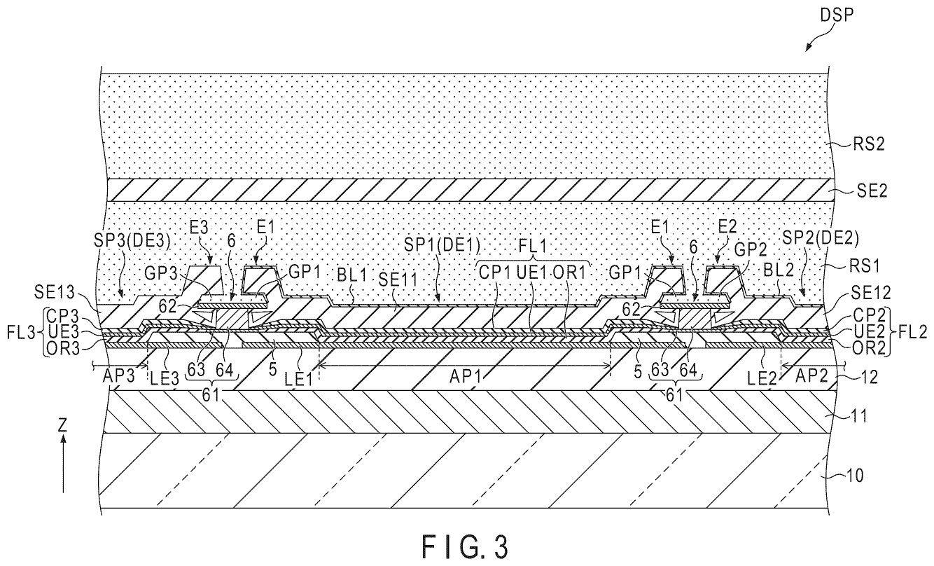

FIG. 3 is a schematic cross-sectional view of the display device DSP along the line III-III of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered by an organic insulating layer 12. The organic insulating layer 12 functions as a planarization film which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered by the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has the width greater than the width of the lower portion 61. That is, the partition 6 has an overhang shape in which both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, the both end portions of the bottom layer 63 protrude relative to the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12 and SE13 (the first to third sealing layers) are provided in the respective subpixels SP1, SP2 and SP3. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

An end portion E1 (the first end portion) of the sealing layer SE11, an end portion E2 (the second end portion) of the sealing layer SE12, and an end portion E3 (the third end portion) of the sealing layer SE13 are each located above the partition 6. In the cross section of FIG. 3, the end portions E1 and E2 are spaced apart from each other on the partition 6 between the subpixels SP1 and SP2. The end portions E1 and E3 are spaced apart from each other on the partition 6 between the subpixels SP1 and SP3.

A gap GP1 (the first gap) is formed between the upper portion 62 and the end portion E1. A gap GP2 (the second gap) is formed between the upper portion 62 and the end portion E2. A gap GP3 (the third gap) is formed between the upper portion 62 and the end portion E3. That is, the upper portion 62 is spaced apart from the end portions E1, E2, and E3 in the third direction Z (the height direction of the partition 6). The stacked films FL1, FL2, and FL3 may be provided in at least a part of the gaps GP1, GP2, and GP3.

At least a part of the sealing layer SE11 is covered by a barrier layer BL1 (the first barrier layer). At least a part of the sealing layer SE12 is covered by a barrier layer BL2 (the second barrier layer). In the example of FIG. 3, the sealing layer SE13 is not covered by a barrier layer. In another example, at least a part of the sealing layer SE13 may be covered by a barrier layer formed of the same material as those of the barrier layers BL1 and BL2.

The sealing layers SE11, SE12, and SE13 and the barrier layers BL1 and BL2 are covered by a resin layer RS1. The resin layer RS1 is covered by the sealing layer SE2. The sealing layer SE2 is covered by a resin layer RS2. The resin layers RS1 and RS2 and the sealing layer SE2 are continuously provided in at least the entire display area DA and partly extend in the surrounding area SA as well.

For example, the gaps GP1, GP2, and GP3 are filled with the resin layer RS1. At least a part of the gaps GP1, GP2, and GP3 may remain as a void not filled with the resin layer RS1 or other layers.

A cover member such as a polarizer, a protective film, and a cover glass may be further provided above the resin layer RS2. This cover member may be attached to the resin layer RS2 via, for example, an adhesive layer such as an optical clear adhesive (OCA). The display device DSP may further comprise a touch detection electrode for detecting a user's touch operation on the display area DA. Such a touch detection electrode can be provided, for example, on the sealing layer SE2.

The organic insulating layer 12 is formed of an organic insulating material such as a polyimide. The rib layer 5 and the sealing layers SE11, SE12, SE13, and SE2 are formed of an inorganic insulating material. In one example, the rib layer 5 is formed of a silicon oxynitride (SiON), and each of the sealing layers SE11, SE12, SE13, and SE2 is formed of a silicon nitride (SiN). Each of the resin layers RS1 and RS2 is formed of, for example, a resinous material (an organic insulating material) such as an epoxy resin or an acrylic resin.

In the present embodiment, the barrier layers BL1 and BL2 each include an oxide. The present embodiment assumes that the oxide is a silicon oxynitride. The barrier layers BL1 and BL2 need not be formed solely of a silicon oxynitride. For example, the barrier layers BL1 and BL2 may be a layer in which a silicon oxynitride and a silicon nitride are mixed.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and OR3 each may have other structures such as a tandem structure including a plurality of light emitting layers.

Each of the cap layers CP1, CP2, and CP3 have, for example, a multilayer structure in which a plurality of transparent layers are stacked. These transparent layers may include a layer formed of an inorganic material and a layer formed of an organic material. The transparent layers have refractive indexes different from each other. For example, the refractive indexes of these transparent layers are different from the refractive indexes of the upper electrodes UE1, UE2, and UE3 and the refractive indexes of the sealing layers SE11, SE12, and SE13. At least one of the cap layers CP1, CP2, and CP3 may be omitted.

For example, each of the bottom layer 63 and the stem layer 64 of the partition 6 is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

For example, the upper portion 62 of the partition 6 includes a stacked layer structure having a lower layer formed of a metal material and an upper layer formed of a conductive oxide. In this case, for the metal material of the lower layer, titanium, a titanium nitride, molybdenum, tungsten, a molybdenum-tungsten alloy, or a molybdenum-niobium alloy may be used. Further, for a conductive oxide of the upper layer, an ITO or an IZO may be used. The upper portion 62 may comprise three or more layers. Alternatively, the upper portion 62 may be formed of a single layer. The upper portion 62 may further include a layer formed of an insulating material.

Common voltage is applied to the partition 6. This common voltage is applied to each of the upper electrodes UE1, UE2, and UE3 in contact with the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light in the blue wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in the red wavelength range.

In another example, the light emitting layers of the organic layers OR1, OR2, and OR3 may emit light of the same color (for example, white). In this case, the display device DSP may comprise a color filter that converts the light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

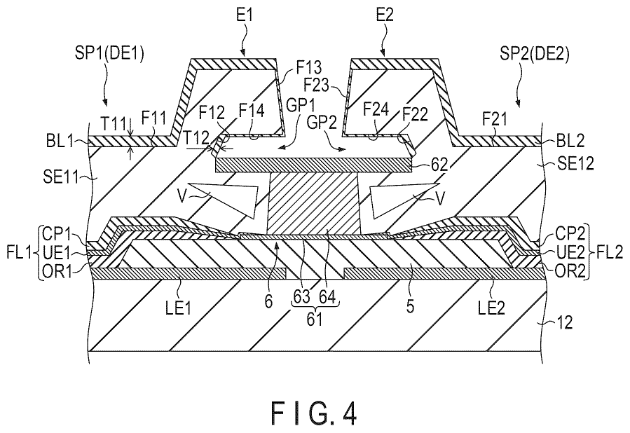

FIG. 4 is a schematic cross-sectional view showing the vicinity of the partition 6 between the subpixels SP1 and SP2 in an enlarged manner. FIG. 4 omits the illustration of the substrate 10, the circuit layer 11, the resin layer RS1, the sealing layer SE2, and the resin layer RS2.

The barrier layer BL1 covers at least a part of an upper surface F11 of the sealing layer SE11 and at least a part of a wall surface F12 at the end of the gap GP1. FIG. 4 shows an example in which the barrier layer BL1 covers the entirety of the upper surface F11 and the wall surface F12.

For example, a thickness T11 of the barrier layer BL1 covering the upper surface F11 is greater than a thickness T12 of the barrier layer BL1 covering the wall surface F12 (T11>T12). The thickness T11 is the average thickness of the barrier layer BL1 covering the upper surface F11. The thickness T12 is an average thickness of the barrier layer BL1 covering the wall surface F12. In one example, the thickness T12 is 10 nm or more and 50 nm or less. The relationship between the thicknesses T11 and T12 is not limited to this example. The thicknesses T11 and T12 may be equivalent to each other.

In the example of FIG. 4, the barrier layer BL1 also covers a side surface F13 of the end portion E1 and a ceiling surface F14 of the gap GP1. For example, the thickness of the barrier layer BL1 covering the side surface F13 and the ceiling surface F14 is smaller than the thicknesses T11 and T12. At least a part of the side surface F13 and the ceiling surface F14 may remain uncovered by the barrier layer BL1.

The barrier layer BL1 is not interposed between the lower portion 61 of the partition 6 and the sealing layer SE11 and between the stacked film FL1 and the sealing layer SE11. That is, the sealing layer SE11 contacts the lower portion 61 (mainly a side surface of the stem layer 64) and the stacked film FL1 (mainly an upper surface of the cap layer CP1).

The relationship between the barrier layer BL2 and the sealing layer SE12 is the same as the relationship between the barrier layer BL1 and the sealing layer SE11. That is, the barrier layer BL2 covers at least a part of an upper surface F21 of the sealing layer SE12 and at least a part of a wall surface F22 at the end of the gap GP2. For example, the thickness of the barrier layer BL2 covering the upper surface F21 is greater than the thickness of the barrier layer BL2 covering the wall surface F22. In one example, the thickness of the barrier layer BL2 covering the wall surface F22 is 10 nm or more and 50 nm or less. The barrier layer BL2 may further cover a side surface F23 of the end portion E2 and a ceiling surface F24 of the gap GP2.

The barrier layer BL2 is not interposed between the lower portion 61 of the partition 6 and the sealing layer SE12 and between the stacked film FL2 and the sealing layer SE12. That is, the sealing layer SE12 contacts the lower portion 61 (mainly the side surface of the stem layer 64) and the stacked film FL2 (mainly an upper surface of the cap layer CP2).

A void V attributable to the partition 6 can be formed in the sealing layers SE11 and SE12 below the upper portion 62 protruding relative to the side surface of the stem layer 64. The same void V can be formed in the sealing layer SE13 shown in FIG. 3. These voids V are not connected to the gaps GP1, GP2, and GP3.

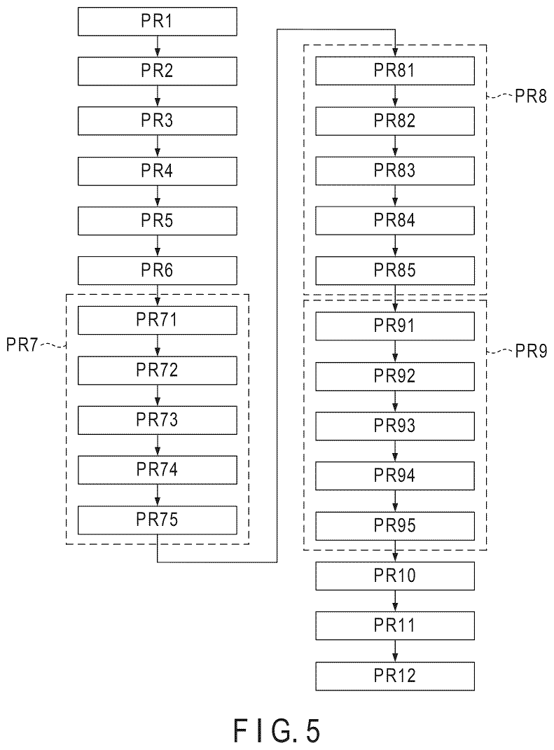

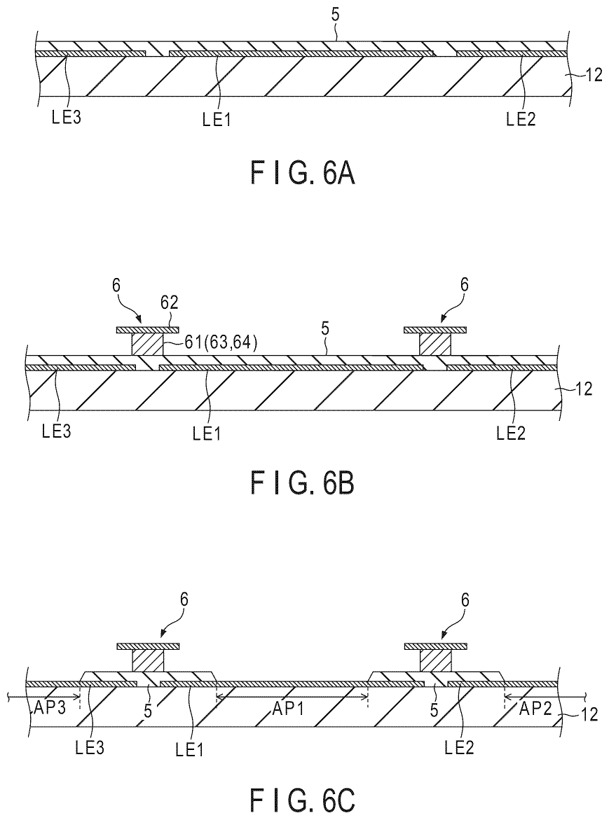

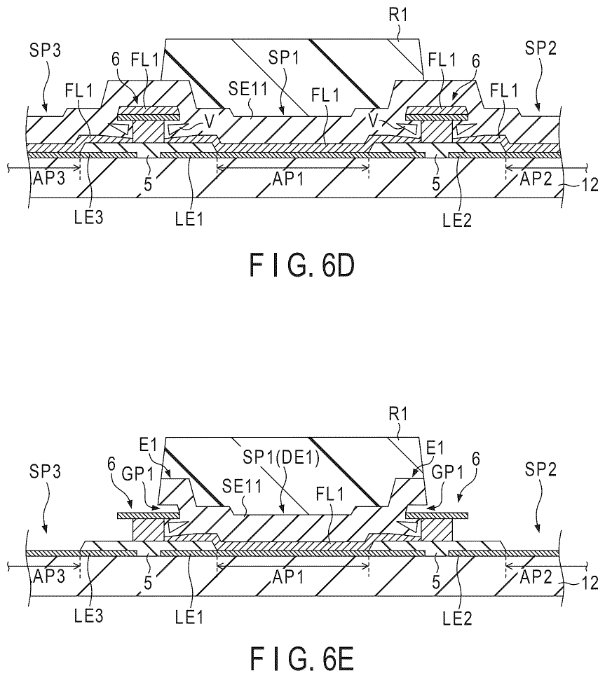

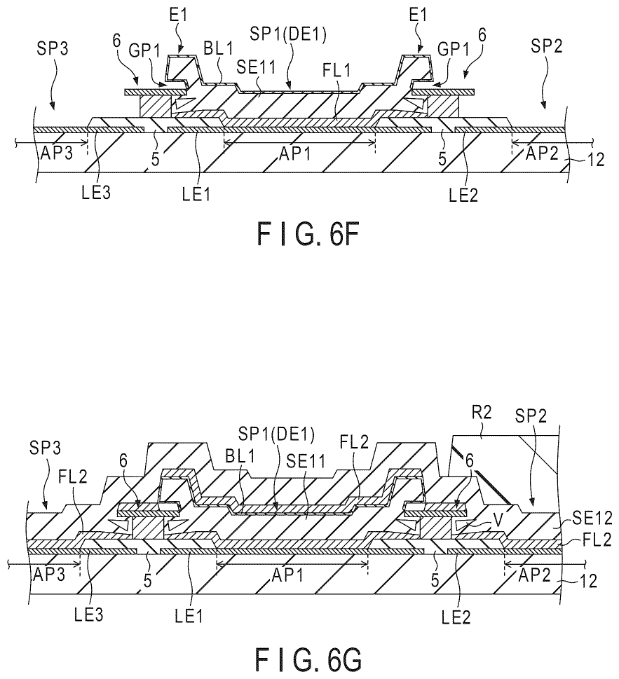

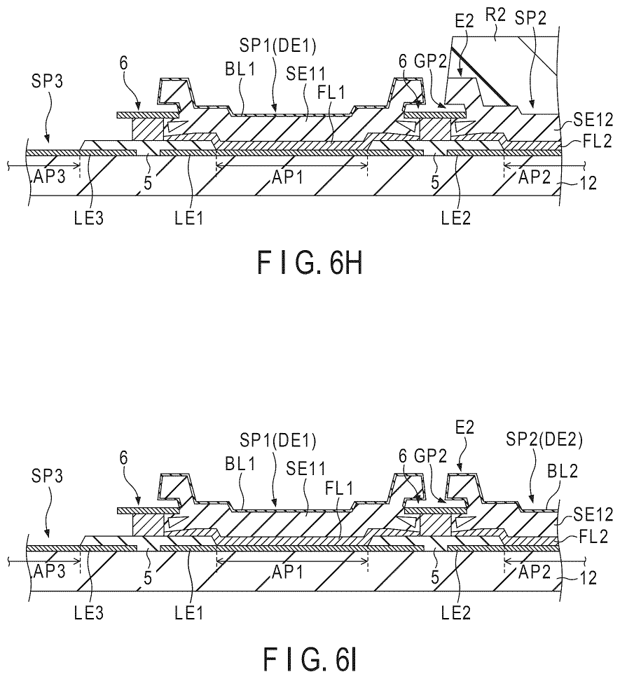

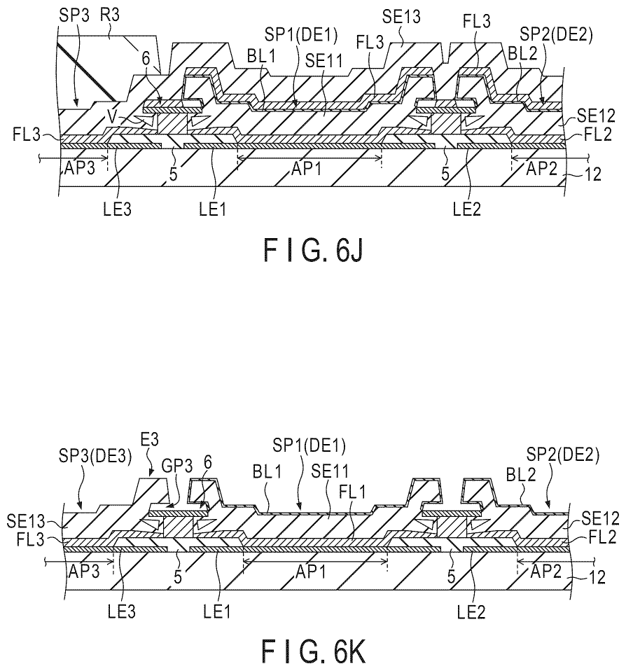

The following describes an example of the manufacturing method of the display device DSP. FIG. 5 is a flowchart showing an example of the manufacturing method of the display device DSP. FIG. 6A to FIG. 6K are schematic cross-sectional views showing the manufacturing process of the display device DSP. FIG. 6A to FIG. 6K mainly focus on the display area DA and omit the illustration of elements under the organic insulating layer 12.

In the manufacturing of the display device DSP, a circuit layer 11 is first formed above the substrate 10 (the process PR1 in FIG. 5). Further, the organic insulating layer 12 covering the circuit layer 11 is formed (the process PR2 in FIG. 5).

After the process PR2, as shown in FIG. 6A, the lower electrodes LE1, LE2, and LE3 are formed on the organic insulating layer 12 (the process PR3 in FIG. 5). Further, the rib layer 5 covering the lower electrodes LE1, LE2, and LE3 is formed (the process PR4 in FIG. 5). At this time, the pixel apertures AP1, AP2, and AP3 are not provided in the rib layer 5. The rib layer 5 can be formed by chemical vapor deposition (CVD).

After the formation of the rib layer 5, the partition 6 is formed on the rib layer 5 as shown in FIG. 6B (the process PR5 in FIG. 5). Further, as shown in FIG. 6C, the pixel apertures AP1, AP2, and AP3 are formed in the rib layer 5 (the process PR6 in FIG. 5). The pixel apertures AP1, AP2, and AP3 may be formed before the formation of the partition 6.

After the process PR6, the display element DE1 is formed (the process PR7 in FIG. 5). In the formation of the display element DE1, a pretreatment is performed to remove residues generated in the processes up to this process (the process PR71 in FIG. 5). For example, the pretreatment includes ashing and pure-water cleaning after the ashing.

Next, as shown in FIG. 6D, the stacked film FL1 and the sealing layer SE11 are formed over the entirety of the display area DA and the surrounding area SA (the process PR72 in FIG. 5). As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD. The CVD may cause insufficient deposition of a material of the sealing layer SE11 on the lateral side of the overhang-shaped partition 6 and may form the void V.

Next, as shown in FIG. 6D, a resist R1 is provided on the sealing layer SE11 (the process PR73 in FIG. 5). The resist R1 covers the subpixel SP1 and a part of the partition 6 around the subpixel SP1.

Thereafter, the etching process using the resist R1 as a mask is performed (the process PR74 in FIG. 5). As shown in FIG. 6E, this etching process removes parts exposed from the resist R1 of the stacked film FL1 and the sealing layer SE11. That is, parts overlapping the lower electrode LE1 of the stacked film FL1 and the sealing layer SE11 remain. The other parts are removed. Thus, the display element DE1 is formed in the subpixel SP1. This etching process may include wet etching and dry etching performed in order for the sealing layer SE11, the cap layer CP1, the upper electrode UE1, and the organic layer OR1. After these etching processes, the resist R1 is removed (stripped) (the process PR75 in FIG. 5).

A chemical solution used in the etching of the stacked film FL1 in the process PR74 or a chemical solution used in the removal of the resist R1 in the process PR75 erodes the stacked film FL1 below the end portion E1 of the sealing layer SE11. This erosion forms the gap GP1 below the end portion E1.

After the process PR75, the display element DE2 is formed (the process PR8 in FIG. 5). In the formation of the display element DE2, residues generated in the formation of the display element DE1 are removed, and a pretreatment for forming the barrier layer BL1 is performed (the process PR81 in FIG. 5). For example, the pretreatment includes a chemical treatment using a mixed acid, an oxygen plasma treatment using oxygen (hereinafter also referred to as oxygen plasma treatment), and a pure-water cleaning after the oxygen plasma treatment.

The oxygen plasma treatment is performed in a chamber to which a gas including oxygen is supplied. Oxidation of the surface layer of the sealing layer SE11 by the oxygen plasma treatment forms, as shown in FIG. 6F, the barrier layer BL1 covering the sealing layer SE11. In other words, when the sealing layer SE11 is formed of a silicon nitride, the oxygen plasma treatment forms a silicon oxynitride film on the sealing layer SE11. This film corresponds to the barrier layer BL1.

After the process PR81, as shown in FIG. 6G, the stacked film FL2 and the sealing layer SE12 are formed over the entirety of the display area DA and the surrounding area SA (the process PR82 in FIG. 5). As shown in FIG. 3, the stacked film FL2 includes the organic layer OR2 contacting the lower electrode LE2 through the pixel aperture AP2, the upper electrode UE2 covering the organic layer OR2, and the cap layer CP2 covering the upper electrode UE2. The organic layer OR2, the upper electrode UE2, and the cap layer CP2 may be formed by, for example, vapor deposition. The sealing layer SE12 may be formed by, for example, CVD. The CVD may cause insufficient deposition of a material of the sealing layer SE12 on the lateral side of the overhang-shaped partition 6 and may form the void V.

Next, as shown in FIG. 6G, a resist R2 is provided on the sealing layer SE12 (the process PR83 in FIG. 5). The resist R2 covers the subpixel SP2 and a part of the partition 6 around the subpixel SP2.

Thereafter, the etching process using the resist R2 as a mask is performed (the process PR84 in FIG. 5). As shown in FIG. 6H, this etching process removes parts exposed from the resist R2 of the stacked film FL2 and the sealing layer SE12. That is, parts overlapping the lower electrode LE2 of the stacked film FL2 and the sealing layer SE12 remain. The other parts are removed. Thus, the display element DE2 is formed in the subpixel SP2. This etching process may include wet etching and dry etching performed in order for the sealing layer SE12, the cap layer CP2, the upper electrode UE2, and the organic layer OR2. After these etching processes, the resist R2 is removed (stripped) (the process PR85 in FIG. 5).

A chemical solution used in etching of the stacked film FL2 in the process PR84 or a chemical solution used in the removal of the resist R2 in the process PR85 erodes the stacked film FL2 below the end portion E2 of the sealing layer SE12. This erosion forms the gap GP2 below the end portion E2.

After the process PR85, the display element DE3 is formed (the process PR9 in FIG. 5). In the formation of the display element DE3, residues generated in the formation of the display element DE2 are removed, and a pretreatment for forming the barrier layer BL2 is performed (the process PR91 in FIG. 5). For example, the pretreatment includes the chemical treatment using a mixed acid, the oxygen plasma treatment, and the pure-water cleaning after the oxygen plasma treatment.

The oxygen plasma treatment is performed in a chamber to which a gas including oxygen is supplied. Oxidation of the surface layer of the sealing layer SE12 by the oxygen plasma treatment forms, as shown in FIG. 6I, the barrier layer BL2 covering the sealing layer SE12. In other words, when the sealing layer SE12 is formed of a silicon nitride, the oxygen plasma treatment forms a silicon oxynitride film on the sealing layer SE12. This film corresponds to the barrier layer BL2.

After the process PR91, as shown in FIG. 6J, the stacked film FL3 and the sealing layer SE13 are formed over the entirety of the display area DA and the surrounding area SA (the process PR92 in FIG. 5). As shown in FIG. 3, the stacked film FL3 includes the organic layer OR3 contacting the lower electrode LE3 through the pixel aperture AP3, the upper electrode UE3 covering the organic layer OR3, and the cap layer CP3 covering the upper electrode UE3. The organic layer OR3, the upper electrode UE3, and the cap layer CP3 may be formed by, for example, vapor deposition. The sealing layer SE13 may be formed by, for example, CVD. The CVD may cause insufficient deposition of a material of the sealing layer SE13 on the lateral side of the overhang-shaped partition 6 and may form the void V.

Next, as shown in FIG. 6J, a resist R3 is provided on the sealing layer SE13 (the process PR93 in FIG. 5). The resist R3 covers the subpixel SP2 and a part of the partition 6 around the subpixel SP2.

Thereafter, the etching process using the resist R3 as a mask is performed (the process PR94 in FIG. 5). As shown in FIG. 6K, this etching process removes parts exposed from the resist R3 of the stacked film FL3 and the sealing layer SE13. That is, parts overlapping the lower electrode LE3 of the stacked film FL3 and the sealing layer SE13 remain. The other parts are removed. Thus, the display element DE3 is formed in the subpixel SP3. This etching process may include wet etching and dry etching performed in order for the sealing layer SE13, the cap layer CP3, the upper electrode UE3, and the organic layer OR3. After these etching processes, the resist R3 is removed (stripped) (the process PR95 in FIG. 5).

A chemical solution used in etching of the stacked film FL3 in the process PR94 or a chemical solution used in the removal of the resist R3 in the process PR95 erodes the stacked film FL3 below the end portion E3 of the sealing layer SE13. This erosion forms the gap GP3 below the end portion E3.

After the formation of the display elements DE1, DE2, and DE3 in this manner, the display device DSP is completed through processes such as the formation of the resin layer RS1 (the process PR10 in FIG. 5), the formation of the sealing layer SE2 (the process PR11 in FIG. 5), and the formation of the resin layer RS2 (the process PR12 in FIG. 5).

The display device DSP and the manufacturing method according to the present embodiment can improve the yield of the display device DSP. The following describes this effect in detail.

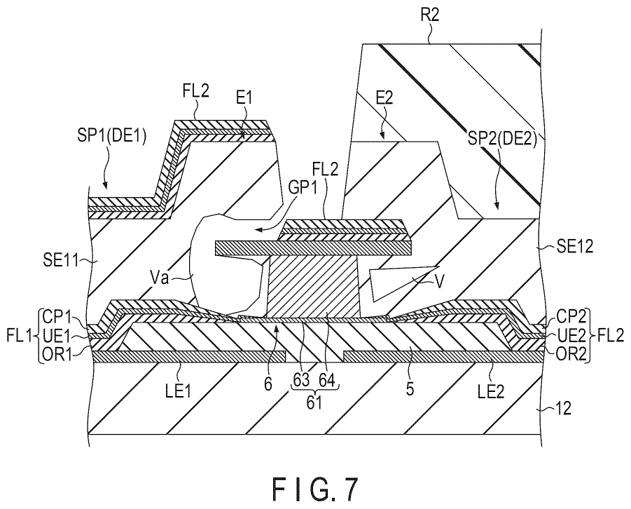

FIG. 7 is a schematic cross-sectional view of the configuration according to a comparative example and shows the vicinity of the end portion E1 of the sealing layer SE11 after the removal of the sealing layer SE12 in the process PR84. The comparative example does not include the barrier layer BL1 covering the sealing layer SE11.

During etching (dry etching) for removing the sealing layer SE12, part exposed from the stacked film FL2 of the sealing layer SE11 is exposed to etching gas, and may be partially eroded. Entry of the etching gas into the gap GP1 expands the gap GP1 toward the stacked film FL1 constituting the display element DE1 and causes the gap GP1 to merge with the void V.

Further erosion of the sealing layer SE11 can form a missing area Va extending from the gap GP1 to the stacked film FL1. A liquid used in various wet etching steps or cleaning after the process PR84 may reach the stacked film FL1 through the missing area Va and cause the stacked film FL1 to disappear or change in quality.

Erosion of the sealing layer SE11 also occurs during the etching of the sealing layer SE13 in the process PR94. The etching of the sealing layer SE13 may also form a missing area in the sealing layer SE12 in the same manner.

In contrast, in the display device DSP according to the present embodiment, the barrier layers BL1 and BL2 are formed for the respective sealing layers SE11 and SE12. Etching conditions for the sealing layers SE11, SE12, and SE13 are defined to suit erosion of materials forming these sealing layers (a silicon nitride in the present embodiment). The barrier layer BL1 including an oxide generated by oxidizing the material (a silicon oxynitride in the present embodiment) has higher resistance to the etching than the material of the sealing layers SE11, SE12, and SE13.

Thus, during the etching of the sealing layers SE12 and SE13, the barrier layer BL1 can suppress erosion of the sealing layer SE11 toward the stacked film FL1 when the barrier layer BL1 covers at least the wall surface F12 at the end of the gap GP1. Similarly, during the etching of the sealing layers SE13, the barrier layer BL2 can suppress erosion of the sealing layer SE12 toward the stacked film FL2 when the barrier layer BL2 covers at least the wall surface F22 at the end of the gap GP2.

A thicker barrier layer BL1 covering the wall surface F12 has a higher effect of suppressing erosion of the sealing layer SE11. Increasing a thickness of the barrier layer BL1 uses a higher oxygen flow rate in the oxygen plasma treatment or a longer treatment time. The oxygen plasma treatment may also oxidize other elements undesirably. Thus, the thickness T12 of the barrier layer BL1 covering the wall surface F12 preferably falls within a range of 10 nm or more and 50 nm or less. The same applies to a thickness of the barrier layer BL2 covering the wall surface F22.

During the etching of the sealing layer SE12, the etching gas can erode the barrier layer BL1 covering the wall surface F12. During this etching, the stacked film FL2 covers the barrier layer BL1 covering the upper surface F11 of the sealing layer SE11. Thus, in the formation of the barrier layer BL1 by the manufacturing method according to the present embodiment, the thickness T11 of the barrier layer BL1 covering the upper surface F11 can become greater than the thickness T12 of the barrier layer BL1 covering the wall surface F12, as described above with reference to FIG. 4.

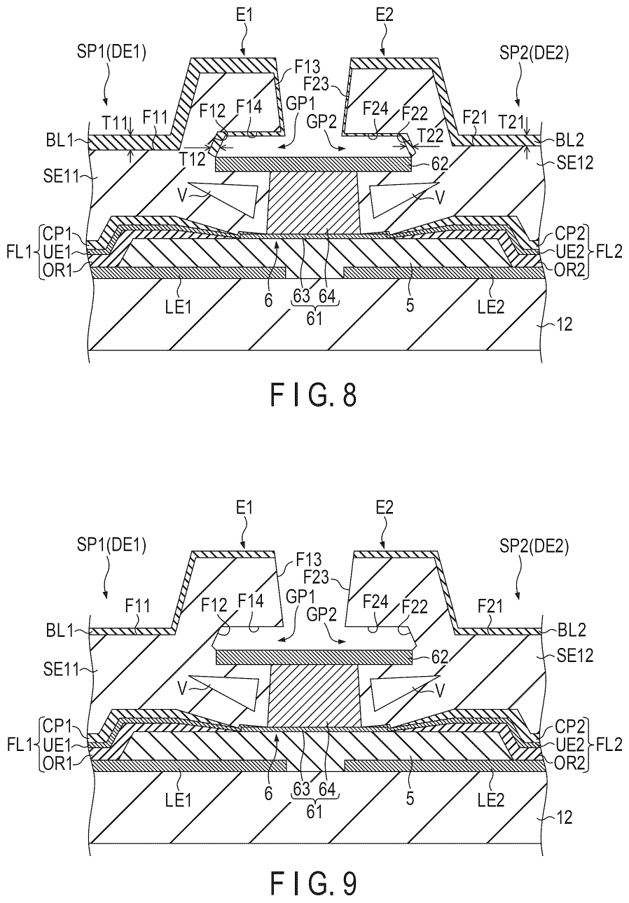

FIG. 8 is a schematic cross-sectional view of the first modified example of the present embodiment. In the same manner as FIG. 4, this figure omits the illustration of the substrate 10, the circuit layer 11, the resin layer RS1, the sealing layer SE2, and the resin layer RS2.

In the first modified example, the thickness T11 of the barrier layer BL1 covering the upper surface F11 is greater than the thickness T21 of the barrier layer BL2 covering the upper surface F21 (T11>T21). The thickness T12 of the barrier layer BL1 covering the wall surface F12 is greater than the thickness T22 of the barrier layer BL2 covering the wall surface F22 (T12>T22). The barrier layer BL1 may be thicker than the barrier layer BL2 at other portions as well.

In the manufacturing method described above, the sealing layer SE11 is exposed to the oxidation plasma treatment in each of the processes PR81 and PR91. The formation of the barrier layers BL1 and BL2 by the manufacturing method described above may make the barrier layer BL1 thicker than the barrier layer BL2 as in the first modified example.

FIG. 9 is a schematic cross-sectional view of the second modified example of the present embodiment. In the same manner as FIG. 4, this figure omits the illustration of the substrate 10, the circuit layer 11, the resin layer RS1, the sealing layer SE2, and the resin layer RS2.

In the second modified example, the barrier layer BL1 is not formed on the wall surface F12, the side surface F13, and the ceiling surface F14. In the same manner, the barrier layer BL2 is not formed on the wall surface F22, the side surface F23, and the ceiling surface F24.

Even when the barrier layer BL1 is formed in the process PR81 and the process PR91, the etching of the sealing layers SE12 and SE13 can erode and eliminate the part covering the wall surface F12, the side surface F13, and the ceiling surface F14. The same applies to the barrier layer BL2. the etching of the sealing layer SE13 can erode and eliminate the part covering the wall surface F22, the side surface F23, and the ceiling surface F24.

In contrast, the barrier layer BL1 covering the upper surface F11 is covered by the stacked film FL2 during the etching of the sealing layer SE12, and is covered by the stacked film FL3 during the etching of the sealing layer SE13. These covers suppress erosion of the barrier layer BL1 covering the upper surface F11. Likewise, the barrier layer BL2 covering the upper surface F21 is covered by the stacked film FL3 during the etching of the sealing layer SE13 and thus is not readily eroded. Thus, the manufacturing method described above can produce the display device DSP having the configuration of the second modified example, depending on conditions of each etching and oxidation plasma treatment.

### Second Embodiment

The following describes the second embodiment. Unless otherwise specified, the configuration of the display device DSP and the processes of the manufacturing method can be the same as those in the first embodiment.

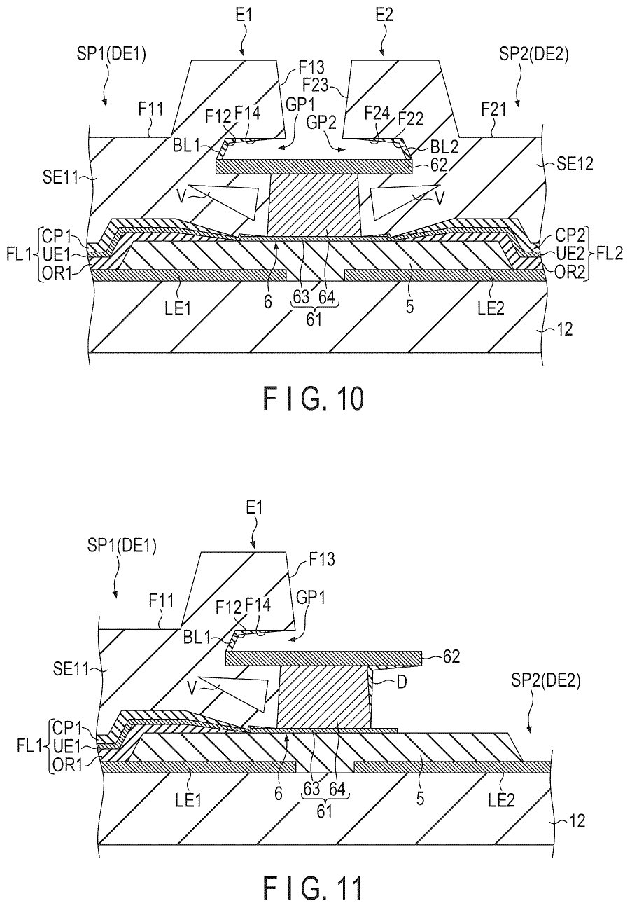

FIG. 10 is a schematic cross-sectional view of the display device DSP according to the second embodiment. In the same manner as FIG. 4, this figure omits the illustration of the substrate 10, the circuit layer 11, the resin layer RS1, the sealing layer SE2, and the resin layer RS2.

In the present embodiment, the barrier layers BL1 and BL2 include a fluoride. In one example, the fluoride is carbon fluoride (CxFy).

In the example of FIG. 10, the barrier layers BL1 and BL2 are formed in the respective gaps GP1 and GP2. Specifically, the barrier layer BL1 covers the wall surface F12 and the ceiling surface F14. The barrier layer BL2 covers the wall surface F22 and the ceiling surface F24.

In the same manner as the first embodiment, the sealing layer SE13 is not covered by a barrier layer such as the barrier layers BL1 and BL2. In another example, a barrier layer may be provided to cover at least a part of the wall surface and the ceiling surface at the end of the gap GP3.

A thickness of the barrier layer BL1 covering the wall surface F12 is not particularly limited, and can be defined within a range of 10 nm or more and 50 nm or less in one example. A thickness of the barrier layer BL2 covering the wall surface F22 can also be defined within a range of 10 nm or more and 50 nm or less in one example.

The display device DSP according to the present embodiment can be manufactured by the same method as the method shown in the flowchart of FIG. 5. The processes PR81 and PR91 perform, instead of the oxygen plasma treatment, a plasma treatment using a carbon tetrafluoride (CF₄) (hereinafter also referred to as a CF₄ plasma treatment).

The CF₄ plasma treatment forms an attachment of a fluoride (for example, a carbon fluoride) in the gaps GP1 and GP2 in which gas tends to stay. These attachments correspond to the barrier layers BL1 and BL2 in the present embodiment.

FIG. 11 is a schematic cross-sectional view describing another example applicable to the manufacturing method of the display device DSP according to the present embodiment. When the CF₄ plasma treatment is performed in the process PR81, an attachment D can also occur below the end portion of the upper portion 62 uncovered by the sealing layer SE11. Such an attachment D can inhibit electrical connection between the partition 6 and the upper electrodes UE2 and UE3 formed thereafter.

Thus, in the process PR81, oxygen plasma treatment for removing the attachment D may be further performed after the CF₄ plasma treatment. This oxygen plasma treatment uses conditions under which the attachment D disappears and the barrier layer BL1 remains. The CF₄ plasma treatment and the oxygen plasma treatment may be performed in the same chamber or in different chambers. The same applies to the process PR91. The process PR91 may further perform the oxygen plasma treatment after the CF₄ plasma treatment.

Even when the barrier layers BL1 and BL2 include a fluoride as in the present embodiment, the barrier layers can suppress disappearance of the sealing layers SE11 and SE12 through the gaps GP1 and GP2 in subsequent etching, as in the first embodiment.

### Third Embodiment

The following describes the third embodiment. Unless otherwise specified, the configuration of the display device DSP and the processes of the manufacturing method can be the same as those in the above embodiments.

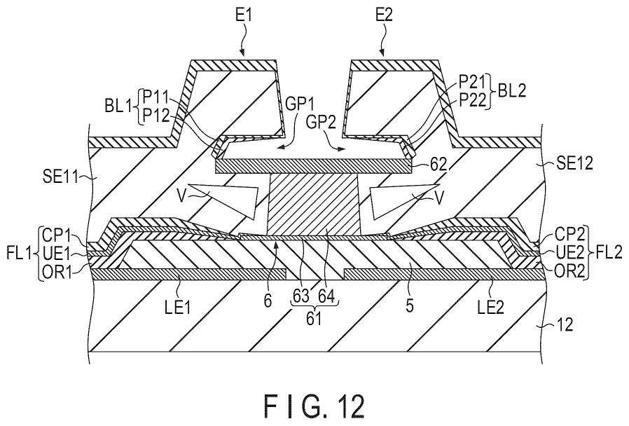

FIG. 12 is a schematic cross-sectional view of the display device DSP according to the third embodiment. In the same manner as FIG. 4, this figure omits the illustration of the substrate 10, the circuit layer 11, the resin layer RS1, the sealing layer SE2, and the resin layer RS2.

In the present embodiment, the barrier layer BL1 includes a first portion P11 and a second portion P12. The barrier layer BL2 includes a first portion P21 and a second portion P22.

The first portions P11 and P21 can be formed by the oxygen plasma treatment performed in the processes PR81 and PR91 in the first embodiment. The second portions P12 and P22 can be formed by the CF₄ plasma treatment performed in the processes PR81 and PR91 in the second embodiment.

The first portions P11 and P21 are layers including an oxide in the same manner as the barrier layers BL1 and BL2 in the first embodiment. The second portions P12 and P22 are layers including a fluoride in the same manner as the barrier layers BL1 and BL2 in the second embodiment. In the example of FIG. 12, the first portions P11 and P21 are formed at the same positions as those of the barrier layers BL1 and BL2 shown in FIG. 4, and the second portions P12 and P22 are formed at the same positions as those of the barrier layers BL1 and BL2 shown in FIG. 10.

A multilayer structure of the barrier layers BL1 and BL2 using different materials as in the present embodiment can more suitably suppress disappearance of the sealing layers SE11 and SE12 through the gaps GP1 and GP2.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

Further, other effects which may be obtained from each of the embodiments and are self-explanatory from the descriptions of the specification or can be arbitrarily conceived by a person of ordinary skill in the art are considered as the effects of the present invention as a matter of course.

What is claimed is

1. A display device, comprising:
a first display element including a first organic layer emitting light in response to application of a voltage;
a partition surrounding the first display element and including a conductive lower portion and an upper portion having an end portion protruding relative to a side surface of the lower portion;
a first sealing layer continuously covering the first display element and a part of the lower portion and having a first end portion spaced apart from the upper portion via a first gap in a height direction of the partition; and
a first barrier layer including an oxide and covering at least a part of an upper surface of the first sealing layer.

2. The display device of claim 1, wherein
the first sealing layer is formed of a silicon nitride, and
the oxide included in the first barrier layer is a silicon oxynitride.

3. The display device of claim 1, wherein
the first barrier layer further covers at least a part of a wall surface at an end of the first gap.

4. The display device of claim 3, wherein
a thickness of the first barrier layer covering the wall surface is 10 nm or more.

5. The display device of claim 3, wherein
a thickness of the first barrier layer covering the wall surface is 50 nm or less.

6. The display device of claim 1, wherein
the first barrier layer further covers at least a part of a ceiling surface of the first gap.

7. The display device of claim 1, wherein
the first barrier layer further covers at least a part of a side surface of the first end portion.

8. The display device of claim 1, further comprising:
a second display element including a second organic layer emitting light in a color different from the first organic layer in response to application of a voltage, the second display element being adjacent to the first display element with the partition interposed therebetween;
a second sealing layer having a second end portion spaced apart from the upper portion via a second gap in the height direction, the second sealing layer continuously covering the second display element and a part of the lower portion; and
a second barrier layer including an oxide and covering at least a part of an upper surface of the second sealing layer.

9. The display device of claim 8, further comprising:
a third display element including a third organic layer emitting light in a color different from the first organic layer and the second organic layer in response to application of a voltage, the third display element being adjacent to the first display element or the second display element with the partition interposed therebetween; and
a third sealing layer including a third end portion spaced apart from the upper portion via a third gap in the height direction, the third sealing layer continuously covering the third display element and a part of the lower portion, wherein
the third sealing layer is not covered by a barrier layer including an oxide.

10. The display device, comprising:
a first display element including a first organic layer emitting light in response to application of a voltage;
a partition surrounding the first display element and including a conductive lower portion and an upper portion having an end portion protruding relative to a side surface of the lower portion;
a first sealing layer having a first end portion spaced apart from the upper portion via a first gap in a height direction of the partition, the first sealing layer continuously covering the first display element and a part of the lower portion; and
a first barrier layer including an oxide, covering at least a part of a wall surface at an end of the first gap, and not being interposed between the lower portion and the first sealing layer.

11. The display device of claim 10, wherein
the first sealing layer is formed of a silicon nitride, and
the oxide included in the first barrier layer is a silicon oxynitride.

12. The display device of claim 10, wherein
a thickness of the first barrier layer covering the wall surface is 10 nm or more.

13. The display device of claim 10, wherein
a thickness of the first barrier layer covering the wall surface is 50 nm or less.

14. The display device of claim 10, further comprising:
a second display element including a second organic layer emitting light in a color different from the first organic layer in response to application of a voltage, the second display element being adjacent to the first display element with the partition interposed therebetween;
a second sealing layer having a second end portion spaced apart from the upper portion via a second gap in the height direction, the second sealing layer continuously covering the second display element and a part of the lower portion; and
a second barrier layer including an oxide, covering at least a part of a wall surface at an end of the second gap, and not being interposed between the lower portion and the second sealing layer.

15. The display device of claim 14, further comprising:
a third display element including a third organic layer emitting light in a color different from the first organic layer and the second organic layer in response to application of a voltage, the third display element being adjacent to the first display element or the second display element with the partition interposed therebetween; and
a third sealing layer including a third end portion spaced apart from the upper portion via a third gap in the height direction, the third sealing layer continuously covering the third display element and a part of the lower portion, wherein
the third sealing layer is not covered by a barrier layer including an oxide.

16. A display device, comprising:
a first display element including a first organic layer emitting light in response to application of a voltage;
a partition surrounding the first display element and including a conductive lower portion and an upper portion having an end portion protruding relative to a side surface of the lower portion;
a first sealing layer having a first end portion spaced apart from the upper portion via a first gap in a height direction of the partition, the first sealing layer continuously covering the first display element and a part of the lower portion; and
a first barrier layer including a fluoride and covering at least a part of a wall surface at an end of the first gap.

17. The display device of claim 16, wherein
the fluoride included in the first sealing layer is a carbon fluoride.

18. The display device of claim 16, wherein
the first barrier layer further includes an oxide covering at least a part of an upper surface of the first sealing layer.

19. The display device of claim 16, further comprising:
a second display element including a second organic layer emitting light in a color different from the first organic layer in response to application of a voltage, the second display element being adjacent to the first display element with the partition interposed therebetween;
a second sealing layer having a second end portion spaced apart from the upper portion via a second gap in the height direction, the second sealing layer continuously covering the second display element and a part of the lower portion; and
a second barrier layer including a fluoride and covering at least a part of a wall surface at an end of the second gap.

20. The display device of claim 19, further comprising:
a third display element including a third organic layer emitting light in a color different from the first organic layer and the second organic layer in response to application of a voltage, the third display element being adjacent to the first display element or the second display element with the partition interposed therebetween; and
a third sealing layer including a third end portion spaced apart from the upper portion via a third gap in the height direction, the third sealing layer continuously covering the third display element and a part of the lower portion, wherein
the third sealing layer is not covered by a barrier layer including a fluoride.
